(19) United States
(12) Patent Application Publication
(10) Pub. No.: US 2006/0121641 A1
(43) Pub. Date: Jun. 8, 2006

(54) Apparatus and method for fabricating nano/micro structure

(75) Inventors: Hong Hocheng, Hsinchu City (TW); Chi-Hung Liao, Tainan City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Hong Hocheng, Hsinchu City (TW)

(21) Appl. No.: 11/060,828

(22) Filed: Feb. 18, 2005

(30) Foreign Application Priority Data
Dec. 6, 2004 (TW) 93137661

(51) Int. Cl. H01L 21/00; C23C 14/00

(52) U.S. Cl. 438/61; 118/50; 977/882

(57) ABSTRACT

An apparatus for fabricating a nano/micro structure is provided in the present invention. The apparatus includes a chamber having a separation device for separating the chamber into a first subchamber and a second subchamber, a dispersion device connected to the first subchamber, an optical driving device disposed next to the first chamber and outside the chamber and an alignment device disposed on the separation device for connecting the first subchamber and the second subchamber. Through the present invention, a plurality of particles are dispersed in the first subchamber via the dispersion device, and further driven and guided to a substrate provided in the second subchamber via the optical driving device and the dispersion device, so that a three-dimensional nano/micro structure on the substrate quickly and precisely.

### FIELD OF THE INVENTION

The present invention relates to an apparatus and a method for fabricating a nano/micro structure, and more particularly to an apparatus and a method for precisely depositing the nano/micro structure on a provided substrate.

### BACKGROUND OF THE INVENTION

Techniques for fabricating nano/micro structures with various materials are highly improved for meeting the increasing demands therefor. The accuracy in a degree of micrometer, nanometer or even an atomic level is applied in the mentioned techniques, such as the micro-contact printing, the scanning probe-based technique, the ink jet printing, the photo-lithography and the laser tweezers, for fabricating the nano/micro structure.

The scanning probe-based technique plays an important role for improving the application of the nano/micro technology. In order to identify the surface property for the sample, scanning by a small probe with a size ranged from 10⁻⁹ m to 10⁻⁷ m, i.e. a nano-level size, or by a microsensor is performed in an extremely short distance from the sample surface, and the information for the sample surface which includes the surface structure, the surface morphology, the electric property, the magnetic property, the optical property and the surface potential is obtained thereby. In addition, through a well control for the probe, the nano/micro particles are able to be moved and further deposited on a substrate. Such a measure, however, brings a small transmission amount of particles and hence results in a low efficiency for fabricating the nano/micro structure thereby. Accordingly, the mentioned fabrication on the basis of the scanning probe-based technique has a limitation in the actual application.

The ink jet printing technique is now broadly applied in the image output application. The inks are heated in the jetting zone so as to form micro bubbles therewith. Ink drops are driven by those micro bubbles and then jetting out from the nozzle. The bubbles will last for several microseconds, and the ink drops will be drawn back into the nozzle while the bubbles are broken or vanished, which further results in a suction at the surface of the ink drops. Hence a new ink drop is subsequently attacked and supplemented into the jetting zone thereby. The nano/micro particles, which are well dispersed in the inks, are able to be deposited on a provided substrate while the ink is jetted and printed thereto, so as to assemble the nano/micro structure thereon. Nevertheless, only an extremely thin pattern layer is produced through the mentioned process which makes it difficult to assemble a three-dimensional nano/micro structure with a high efficiency.

The photo-lithography technique has been increasingly developed for the semiconductor technology. The basic processing steps involved in the photo-lithography technique includes photoresist coating, exposing and chemically etching which causes the pollution for the environment and results in a limited application in certain materials. Such a technique is not adopted in the organic or the biological structure fabrication accordingly. Furthermore, the thickness of the structure fabricated thereby is ranged in a submicron level, i.e. a range between 0.01 μm, and 1 μm, due to the focal distance. Such a technique is only suitable for fabricating a planar structure but fails to efficiently assemble a three-dimensional nano/micro structure, which has a height larger than 1 μm.

As to the laser tweezers, the principle adopted therein is to control the movement of nano/micro particles via a movable focused laser, so that a nano/micro structure is further formed on the provided substrate thereby. However, since the lens with a large numerical aperture (NA) is necessary for the laser tweezers to focus the laser, hence the operation distance thereof is limited. Therefore, such a technique also fails to assemble a nano/micro structure with an increased scale. In addition, a great amount of energy resulted from the highly focused laser may cause great damage to the material to be assembled, and in particular to the biomaterials to be assembled.

Furthermore, regarding the process for fabricating the nano/micro structure via the laser tweezers, the nano/micro particles are firstly grabbed and transmitted by the laser tweezers and then releases on a certain position of the provided substrate. A two-dimensional or three-dimensional nano/micro structure is assembled on the provided substrate while a repeated process of particle grabbing, transmitting and releasing is performed. However, the amount of the particles transmitted via the laser tweezers is small and the operation distance therefor is short which result in a limited efficiency for the laser tweezers. Therefore, the laser tweezers still fails to be applied for the two-dimensional or three-dimensional nano/micro structure fabrication.

In order to overcome the mentioned drawbacks in this art, a novel apparatus and a method for fabricating a nano/micro structure are provided. In the present invention, a plurality of particles are dispersed in a first subchamber via a dispersion device, and further driven and guided to a substrate provided in a second subchamber via an optical driving device and the dispersion device, so as to form a nano/micro structure on the provided substrate. Compared with the conventional apparatuses and methods for the nano/micro structure fabrication, the present invention provides a much simplified apparatus and method for fabricating a precise nano/micro structure with a high efficiency.

### SUMMARY OF THE INVENTION

In accordance with a first aspect of the present invention, an apparatus for fabricating a nano/micro structure is provided. The apparatus includes a chamber having a separation device for separating the chamber into a first subchamber and a second subchamber, a dispersion device connected to the first subchamber, an optical driving device disposed next to the first chamber and outside the chamber and an alignment device disposed on the separation device for connecting the first subchamber and the second subchamber.

Preferably, a plurality of particles are dispersed in the first subchamber via the dispersion device, and further driven and guided to a substrate provided in the second subchamber via the optical driving device and the dispersion device, so as to form the nano/micro structure on the substrate.

Preferably, the apparatus further includes a monitoring device configured next to the second chamber and outside the chamber for monitoring a formation of the nano/micro structure.

Preferably, the monitoring device is one of a charge coupled device (CCD) and a microscope.

Preferably, the monitoring device is connected to a computer.

Preferably, the chamber is a separated chamber.

Preferably, the chamber further includes a holder therein.

Preferably, the holder is one of a movable holder and a stationary holder.

Preferably, the substrate is provided on the holder.

Preferably, the optical driving device includes a laser system.

Preferably, the optical driving device further includes a lens.

Preferably, the lens has a relatively reduced numerical aperture (NA).

In accordance with a second aspect of the present invention, an apparatus for fabricating a nano/micro structure with different particles is provided. The provided apparatus includes a chamber separated into a first subchamber and a second subchamber, a dispersion device connected to the first subchamber, at least two optical driving devices configured next to the first subchamber and outside the chamber and an alignment device connecting the first subchamber and the second subchamber.

Preferably, a plurality of particles are dispersed in the first subchamber via the dispersion device, and further driven and guided to a substrate provided in the second subchamber via the optical driving devices and the dispersion device, so as to form the nano/micro structure on the substrate.

In accordance with a third aspect of the present invention, a method for fabricating a nano/micro structure is provided. The method includes steps of providing a substrate, providing plural particles, dispersing the particles, providing an optical driving device for optically driving the dispersed particles forward and introducing the particles to the substrate to be deposited thereon to form the nano/mirco structure.

Preferably, the method further includes a step of monitoring a formation of the nano/micro structure.

Preferably, the formation of the nano/micro structure is monitored by a monitoring device of a charge coupled device (CCD) and a microscope.

Preferably, the monitoring device is connected to a computer.

Preferably, the chamber further includes a holder therein.

Preferably, the holder is one selected from a movable holder and a stationary holder.

Preferably, the substrate is provided on the holder.

Preferably, the dispersed particles are optically driven by a laser system.

The foregoing and other features and advantages of the present invention will be more clearly understood through the following descriptions with reference to the drawings, wherein:

### BRIEF DESCRIPTION OF THE DRAWINGS

FIG. 1 is a diagram illustrating an apparatus for fabricating a nano/micro structure according to a first preferred embodiment of the present invention;

FIG. 2 is a diagram illustrating an apparatus for fabricating a nano/micro structure according to a second preferred embodiment of the present invention; and

FIG. 3 is a flow chart for illustrating the method for fabricating a nano/micro structure according to the preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

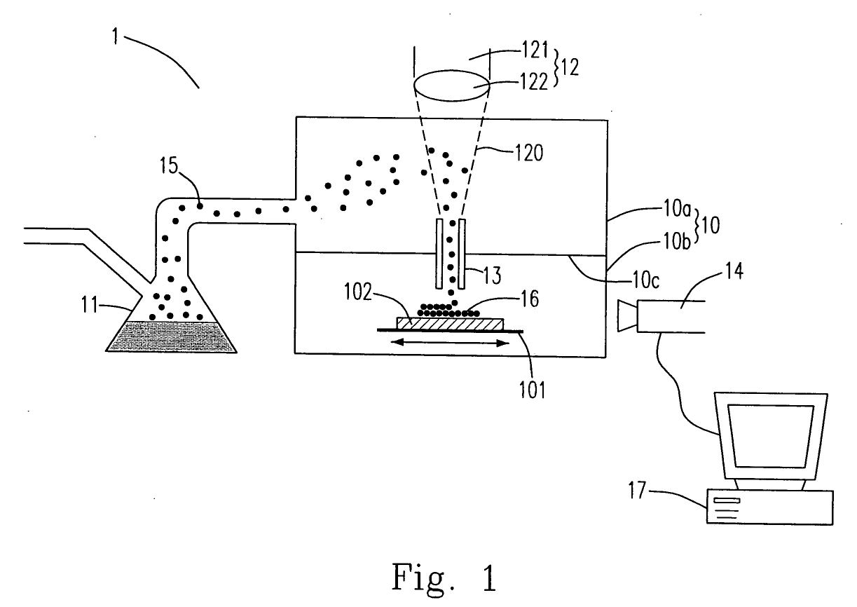

Please refer to FIG. 1, which schematically illustrates the apparatus for fabricating a nano/micro structure according to the first preferred embodiment of the present invention. The nano/micro structure is formed in a vacuum or vaporized condition. The apparatus 1 typically includes a chamber 10, a dispersion device 11, an optical driving device 12 and an alignment device 13. The chamber 10 includes a separation device 10c therein, so that the chamber 10 is further separated into a first subchamber 10a and a second subchamber 10b , and the alignment device 13 is configured on the separation device 10c. Plural nano/micro particles 15 are uniformly dispersed into the first subchamber 10a via the dispersion device 11, and then the dispersed nano/micro particles 15 are further guided and transmitted to an entry of the alignment device 13 by the optical driving device 12. The optical driving device 12 provides a precise guidance for the dispersed nano/micro particles 15, so that the dispersed nano/micro particles 15 are able to be well transmitted to the alignment device 13, and after passing therethrough, they are precisely deposited on the substrate 102 in the second subchamber 10b. The three-dimensional nano/micro structure 16 is assembled thereby.

The substrate 102 is disposed on a holder 101 in the second subchamber 10b, wherein the holder 101 is each of a movable holder or a stationary holder. In this case, the holder 101 is reciprocated in a horizontal direction as shown in FIG. 1, and this results in a relative movement between the substrate 102 and the alignment device 13. Such a relative movement benefits the nano/micro particles 15 to further assemble the nano/micro structure 16 on the substrate 102.

In this case, the dispersion device 11 is each of a pump, a piezo-actuator and a sprayer. Besides, a design involved the supersonic oscillation is also preferred. The alignment device 13 includes one of a hollow optical fiber, a capillary or any other fine tubes which makes the dispersed nano/micro particles 15 to be localized in a certain direction toward the position for the deposition.

Moreover, the optical driving device 12 is a laser system 121, which produces a laser 120 for the nano/micro particles 15. The nano/micro particles 15 are guided in a more limited and precise direction and range thereby. The optical driving device 12 further includes a lens 122 with a relatively reduced numerical aperture (NA), so that the laser 120 propagating therethrough would be focused and the nano/micro particles 15 are hence attracted in a limited range due to the gradient force generated from the focused laser. This makes the nano/micro particles 15 unhindered and hence the nano/micro particles 15 may pass through the alignment device 13 without any particle attaching thereto.

Furthermore, the apparatus 1 also has a monitoring device 14 for monitoring the formation and assembling of the nano/micro structure. The monitoring device 14 is configured next to the second chamber 10b and outside the chamber 10, and selected from a charge coupled device (CCD), a microscope or any other types thereof. Besides, the monitoring device 14 is further connected to a computer 17 for taking account of the operation convenience. In other words, depending on the formation and assembling of the nano/micro structure 16, an immediate adjustment, such as controlling the movement of the holder 101, is performed via the computer 17, and this is more advantageous for fabricating the desired nano/micro structure 16.

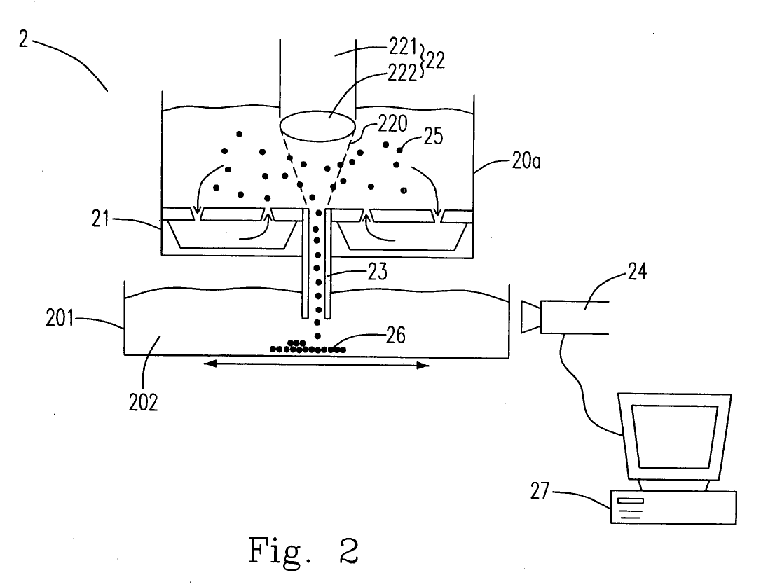

Please refer to FIG. 2, which schematically illustrates the apparatus for fabricating a nano/micro structure according to the second preferred embodiment of the present invention. The apparatus 2 is applied for performing the formation of a nano/micro structure 26 on a substrate 202 in a liquid condition. The apparatus 2 mainly includes a dispersion device 21, an optical driving device 22, a alignment device 23, a monitoring device 24 and a computer 27, wherein the optical driving device 22 is a laser system 221 having a lens 222 therein to produce the focused laser 220 for guiding the nano/micro particles 25.

The difference between the first and the second preferred embodiments is that in this case, the dispersion device 21 is disposed in the first subchamber 20a. The nano/micro particles 25 therein are well dispersed by the dispersion device 21, and then are guided to pass through the alignment device 23 by the laser 220 generated from the optical driving device 22. The nano/micro particles 25 passing through the alignment device 23 are further deposited onto the substrate 202 on the holder 201, which is in a liquid condition. Moreover, the holder 201 is reciprocated in a horizontal direction as shown in FIG. 2, and this results in a relative movement between the substrate 202 and the alignment device 23. Such a relative movement provides a precisely control for the nano/micro particles 15, so as to further assemble the nano/micro structure 26 on the substrate 202.

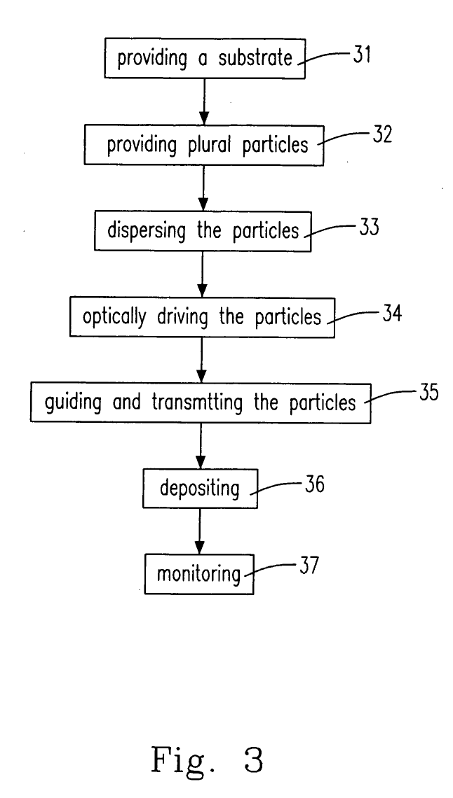

Please refer to FIG. 3, which is a flow chart for schematically illustrating the method for fabricating a nano/micro structure according to the preferred embodiment of the present invention. First, a substrate is provided in a chamber including a vacuum, a vaporized or a liquid condition as shown in step 31. Then, plural particles are provided as shown in step 32. Afterward, the provided particles are well dispersed into a plurality of nano/micro particles as shown in step 33. Subsequently, a laser is generated and focused via an optical driving device including a laser system and a lens for optically driving the plurality of nano/micro particles forward as shown in step 34. Finally, the plurality of nano/micro particles are further guided and introduced to the substrate to be deposited thereon to form a three-dimensional nano/mirco structure as shown in step 35. In addition, the formation of the three-dimensional nano/mirco structure is further improved through a relative movement between the substrate and the alignment device, and the formation of the three-dimensional nano/mirco structure is further monitored, and the movement of the substrate is further controlled via a monitoring device and a computer connected thereto which are respectively shown in steps 36 and 37.

A whole and complete nano/micro planar structure, i.e. the two-dimensional nano/micro structure, is able to be assembled simultaneously by the apparatus and the relevant method of the present invention. Furthermore, through the relative movement between the substrate and the alignment device, an optional three-dimensional nano/micro structure is also assembled in a much quicker and simplified manner. In addition, since the particles are dispersed and transmitted in an isolated chamber, the nano/micro structure on the substrate are prevented from suffering the contamination of self-excited particles and being influenced by any external factors. Hence the efficiency for the nano/micro structure assembling is increasingly improved by the present invention.

According to the present invention, the nano/micro particles are successively guided and transmitted to the provided substrate, so as to assemble a three-dimensional nano/micro structure on the substrate quickly and precisely. Besides, an experimental result shows that a particle transmission rate for the apparatus provided in the present invention is up to 10⁷ Hz, and the fabricated structure has a line width of a nanometer scale. Furthermore, an arrangement including plural optical driving devices of the present invention is also preferred, so that the particles of various materials are able to be simultaneously deposited on a common substrate thereby. The drawback of the material limitation in the conventional apparatus and method is also overcome, and materials including the semiconductor, the metal, the cell, the enzyme and a variety of organic or inorganic materials are able to be applied for the present invention. Since the photo resists and etchants are not necessary for the present invention, the production cost for fabricating the nano/micro structure is efficiently reduced and such a fabrication would not cause damages and pollutions to the environment. Therefore, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An apparatus for fabricating a nano/micro structure, comprising:
a chamber having a separation device for separating said chamber into a first subchamber and a second subchamber;
a dispersion device connected to said first subchamber;
an optical driving device disposed next to said first chamber and outside said chamber; and
an alignment device disposed on said separation device for connecting said first subchamber and said second subchamber,
wherein a plurality of particles are dispersed in said first subchamber via said dispersion device, and further driven and guided to a substrate provided in said second subchamber via said optical driving device and said dispersion device, so as to form said nano/micro structure on said substrate.

2. The apparatus according to claim 1, further comprising a monitoring device configured next to said second chamber and outside said chamber for monitoring a formation of said nano/micro structure.

3. The apparatus according to claim 2, wherein said monitoring device is one of a charge coupled device (CCD) and a microscope.

4. The apparatus according to claim 2, wherein said monitoring device is connected to a computer.

5. The apparatus according to claim 1, wherein said chamber is a separated chamber.

6. The apparatus according to claim 1, wherein said chamber further comprises a holder therein.

7. The apparatus according to claim 6, wherein said holder is one of a movable holder and a stationary holder.

8. The apparatus according to claim 7, wherein said substrate is provided on said holder.

9. The apparatus according to claim 1, wherein said optical driving device comprises a laser system.

10. The apparatus according to claim 9, wherein said optical driving device further comprises a lens.

11. The apparatus according to claim 10, wherein said lens has a relatively reduced numerical aperture (NA).

12. An apparatus for fabricating a nano/micro structure, comprising:
a chamber separated into a first subchamber and a second subchamber;
a dispersion device connected to said first subchamber;
at least two optical driving devices configured next to said first subchamber and outside said chamber; and
an alignment device connecting said first subchamber and said second subchamber,
wherein a plurality of particles are dispersed in said first subchamber via said dispersion device, and further driven and guided to a substrate provided in said second subchamber via said optical driving devices and said dispersion device, so as to form said nano/micro structure on said substrate.

13. A method for fabricating a nano/micro structure, comprising steps of:
(a) providing a substrate;
(b) providing plural particles;
(c) dispersing said particles;
(d) providing an optical driving device for optically driving said dispersed particles forward; and
(e) introducing said particles to said substrate to be deposited thereon to form said nano/mirco structure.

14. The method according to claim 13, after step (e) further comprising a step (f) of:
monitoring a formation of said nano/micro structure.

15. The method according to claim 14, wherein said formation of said nano/micro structure is monitored by a monitoring device of a charge coupled device (CCD) and a microscope.

16. The method according to claim 15, wherein said monitoring device is connected to a computer.

17. The method according to claim 13, wherein said chamber further comprises a holder therein.

18. The method according to claim 17, wherein said holder is one selected from a movable holder and a stationary holder.

19. The method according to claim 18, wherein said substrate is provided on said holder.

20. The method according to claim 13, wherein said dispersed particles are optically driven by a laser system.
